(19) United States
(12) Patent Application Publication
(10) Pub. No.: US 2022/0020671 A1
(43) Pub. Date: Jan. 20, 2022

(54) FLIP-STACK TYPE SEMICONDUCTOR PACKAGE AND METHOD OF MANUFACTURING THE SAME

(71) Applicant: Electronics and Telecommunications Research Institute, Daejeon (KR)

(72) Inventors: Dong Yun JUNG, Daejeon (KR); Hyun Gyu JANG, Daejeon (KR); Sung Kyu KWON, Daejeon (KR); Kun Sik PARK, Daejeon (KR); Jong Il WON, Daejeon (KR); Seong Hyun LEE, Daejeon (KR); Jong Won LIM, Daejeon (KR); Doo Hyung CHO, Daejeon (KR)

(73) Assignee: Electronics and Telecommunications Research Institute, Daejeon (KR)

(21) Appl. No.: 17/380,583

(22) Filed: Jul. 20, 2021

(30) Foreign Application Priority Data
Jul. 20, 2020 (KR) 10-2020-0089830
Feb. 16, 2021 (KR) 10-2021-0020720

(51) Int. Cl. H01L 23/495; H01L 23/00

(52) U.S. Cl. CPC H01L 23/49562; H01L 23/49524; H01L 2224/83801; H01L 24/83; H01L 23/49575

(57) ABSTRACT

The present invention minimizes parasitic inductance at the time of packaging a semiconductor that requires high efficiency and high-speed switching driving. In implementing a semiconductor package composed of one or more switching devices and one or more diode devices, the present invention provides a flip-stack structure in which a switching device is mounted on an insulating substrate or a metal frame, a flat metal is bonded onto the switching device, and a diode device is flipped and stacked on the flat metal, and accordingly, the flat metal with a large area is used for connection between the devices and between the devices and the insulating substrate, thereby minimizing parasitic inductance generated at a time of semiconductor packaging and automating the entire process of the semiconductor packaging.

### CROSS-REFERENCE TO RELATED APPLICATION

This application claims priority to and the benefit of Korean Patent Applications, No. 10-2020-0089830 filed on Jul. 20, 2020 and No. 10-2021-0020720 filed on Feb. 16, 2021, the disclosures of which are incorporated herein by reference in their entirety.

### BACKGROUND

### 1. Field of the Invention

The present invention relates to packaging a semiconductor, and more particularly, to a flip-stack type semiconductor package and a method of manufacturing the same.

### 2. Discussion of Related Art

Recently, there has been a rapid increase in interest in high efficiency and miniaturization of electrical and electronic equipment. As a result, research on a compound power semiconductor such as silicon carbide (SiC), gallium nitride (GaN), and the like which are capable of higher power density, high temperature stability, and high-speed switching compared to a conventional Si-based power semiconductor is being actively conducted. In particular, a high voltage application of 600 V or more requires semiconductor devices such as an SiC metal-oxide-semiconductor field-effect transistor (MOSFET), SiC Schottky barrier diode (SBD), etc., and power modules to which these devices are applied, or a semiconductor package for specific application.

However, as a switching speed increases, there is a problem that ringing (or oscillation) and over-shoot (or voltage surge) occur due to parasitic inductance generated during packaging. This will be described in detail.

FIG. 1 is an exemplary circuit diagram of a conventional half-bridge power module in which MOSFETs and SBDs are connected in parallel with six in each row in two rows on a high-side (HS) and a low-side (LS). A cathode C and an anode A of each SBD are connected to a drain D and a source S of each MOSFET. HS-G indicates a gate of the MOSFET in the HS row, and LS-G indicates a gate of the MOSFET in the LS row. In this half-bridge circuit, drains of the MOSFETs in the HS row are gathered to form a drain terminal (Drain) of the power module, and sources of the MOSFETs in the LS row are gathered to form a source terminal (Source) of the power module. In addition, a portion in which sources of the MOSFETs in the HS row and drains of the MOSFETs in the LS row are connected is an output terminal (Output) of the power module.

In order to actually implement the half-bridge power module of FIG. 1, a layout of an insulating substrate is designed and devices are disposed thereon to connect the devices to the devices, and the devices to the substrate via bonding wires.

FIG. 2A is an exemplary view of an actual form of a switching device such as MOSFET, etc. A source electrode divided into three parts and a gate electrode are positioned on a top surface, and a drain electrode is positioned on a bottom surface (not shown in FIG. 2A) to be soldered to a metal pattern of an insulating substrate. FIG. 2B is an exemplary view of an actual form of a diode device such as SBD, etc. An anode is formed on a top surface, and a cathode is positioned on a bottom surface (not shown in FIG. 2B) to be soldered to the metal pattern of the insulating substrate.

Here, parasitic inductance is generated due to the bonding wire and the metal pattern on the insulating substrate, thereby causing ringing (or oscillation) and over-shoot (or voltage surge). FIGS. 3A and 3B show schematic waveforms of the ringing and over-shoot. FIG. 3A shows a waveform when the device is turned on, and FIG. 3B shows a waveform when the device is turned off. In FIG. 3A, it can be seen that ringing and/or over-shoot occurs at a Lo-Hi switching timing of a gate-source voltage V_GS and a transition timing of a drain-source voltage V_DS and a drain-source current I_DS accordingly. Also, in FIG. 3B, it can be seen that ringing and over-shoot occur at a Hi-Lo switching timing of the gate-source voltage V_GS and a transition timing of the drain-source current I_DS and the drain-source voltage V_DS accordingly.

### SUMMARY OF THE INVENTION

The present invention is directed to propose a method for minimizing parasitic inductance at a time of packaging a semiconductor that requires high efficiency and high-speed switching driving in order to solve the above-described problems.

In order to achieve the above object, in implementing a semiconductor package composed of one or more switching devices and one or more diode devices, the present invention provides a flip-stack type structure in which a switching device is mounted on an insulating substrate or a metal frame, a flat metal is bonded on the switching device, and a diode device is flipped and stacked on the flat metal, and accordingly, the flat metal with a large area is used for connection between the devices and between the device and the insulating substrate, thereby minimizing parasitic inductance generated at a time of semiconductor packaging and automatizing the entire process of the semiconductor packaging.

Specifically, according to an aspect of the present invention, there is provided a flip-stack type semiconductor package including an insulating substrate, one or more switching devices mounted on the insulating substrate, a first flat metal positioned on a top surface of the switching device, and one or more diode devices flip-stacked on the first flat metal.

In addition, according to another aspect of the present invention, there is provided a method of manufacturing a semiconductor package including: forming a switching device soldering region and a first flat metal soldering region on an insulating substrate; applying solder to the switching device soldering region and the first flat metal soldering region, which are formed on the insulating substrate, and mounting one or more switching devices in the switching device soldering region; applying solder to a first electrode on a top surface of the switching device and mounting a first flat metal in the first flat metal soldering region on which the solder is applied and which is formed on the insulating substrate; applying solder to a first flat metal region to which a diode device is bonded, and flipping and mounting the diode device so that the diode device is in contact with the first flat metal region on which the solder is applied; and soldering and bonding the switching device, the diode device, the first flat metal, and the insulating substrate at the same time.

The above-described configurations and operations of the present invention will become more apparent from embodiments described in detail below with reference to the drawings.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is an exemplary circuit diagram of a conventional half-bridge power module consisting of metal-oxide-semiconductor field-effect transistors (MOSFETs) and Schottky barrier diodes (SBDs);

FIG. 2A is an exemplary view of an actual form of an device of the MOSFET;

FIG. 2B is an exemplary view of an actual form of an device of the SBD;

FIG. 3A and FIG. 3B are views showing a voltage waveform and current waveform of each part when the power module of FIG. 1 is switched;

FIG. 4A is a three-dimensional schematic diagram of a flip-stack type semiconductor package according to an embodiment of the present invention;

FIG. 4B is a plan view of the flip-stack type semiconductor package according to the embodiment of the present invention;

FIG. 4C is a front view of the flip-stack type semiconductor package according to the embodiment of the present invention;

FIG. 5A is a perspective view of a first flat metal of the flip-stack type semiconductor package according to the embodiment of the present invention;

FIG. 5B is a perspective view of a second flat metal of the flip-stack type semiconductor package according to the embodiment of the present invention;

FIG. 5C is a perspective view of a third flat metal of the flip-stack type semiconductor package according to the embodiment of the present invention;

FIG. 6A is a three-dimensional schematic diagram of a flip-stack type semiconductor package according to another embodiment of the present invention;

FIG. 6B is a perspective view of a first flat metal of the flip-stack type semiconductor package according to another embodiment of the present invention;

FIG. 6C is a perspective view of a third flat metal of the flip-stack type semiconductor package according to another embodiment of the present invention;

FIG. 7A is a circuit diagram in which a MOSFET and an SBD are connected in parallel;

FIG. 7B is a circuit diagram in which a plurality of MOSFETs and a plurality of SBDs are connected in parallel;

FIG. 7C is a half-bridge circuit diagram in which SBDs are connected in parallel to each of upper and lower sides of MOSFETs connected in series; and

FIG. 7D is a half-bridge circuit diagram in which a plurality of MOSFETs and a plurality of SBDs are connected in parallel.

### DETAILED DESCRIPTION OF EXEMPLARY EMBODIMENTS

Advantages and features of the present invention and methods for achieving them will be made clear from embodiments described in detail below with reference to the accompanying drawings. However, the present invention may be embodied in many different forms and should not be construed as being limited to the embodiments set forth herein. Rather, these embodiments are provided so that this disclosure will be thorough and complete and will fully convey the scope of the present invention to those of ordinary skill in the technical field to which the present invention pertains. The present invention is defined by the claims. In addition, terms used herein are for the purpose of describing the embodiments and are not intended to limit the present invention. As used herein, the singular forms include the plural forms as well unless the context clearly indicates otherwise. The term “comprise” or “comprising” used herein does not preclude the presence or addition of one or more other elements, steps, operations, and/or components other than stated elements, steps, operations, and/or components.

Hereinafter, exemplary embodiments of the present invention will be described in detail with reference to the accompanying drawings. In adding reference numerals to devices of each drawing, the same devices may have the same reference numeral as possible even if the devices are shown in different drawings. Further, in describing the present invention, the detailed description of a related known configuration or function will be omitted when it obscures the gist of the present invention.

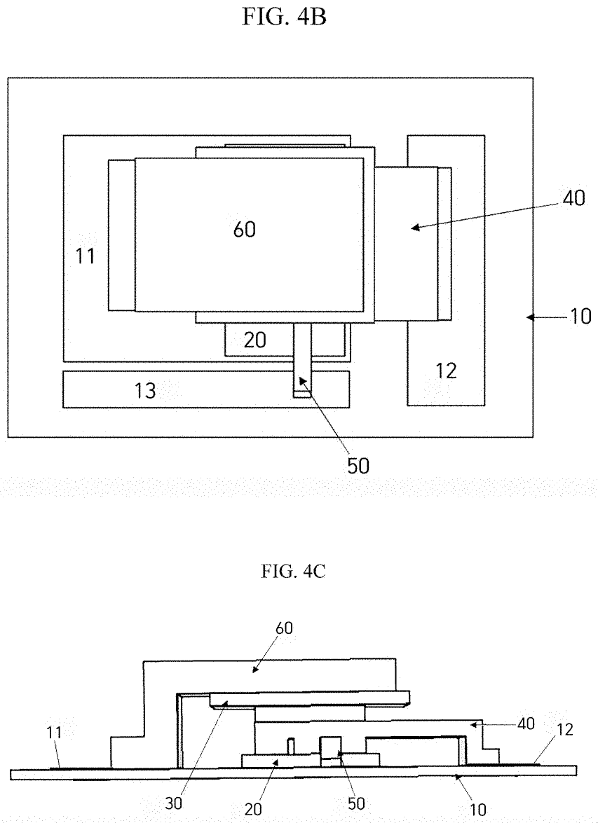

FIGS. 4A to 4C are a perspective view, a plan view, and a front view of a flip-stack type power module package according to an embodiment of the present invention, respectively. This embodiment shows a power module in which one MOSFET and one SBD are connected.

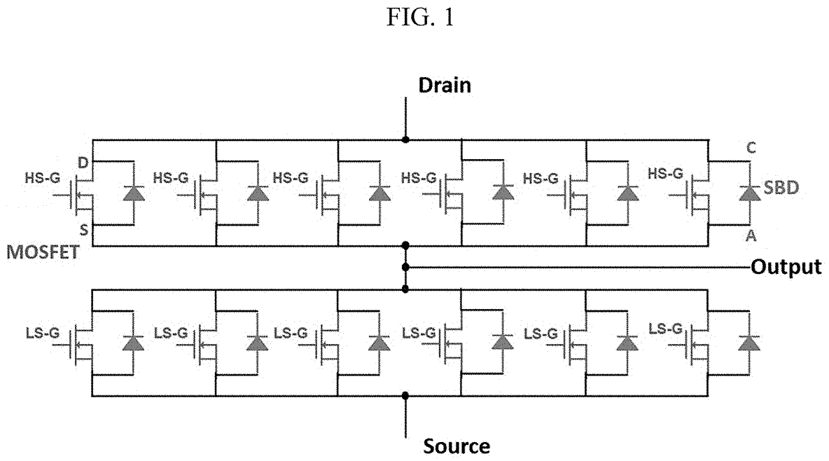

In general, when manufacturing a power module in which one or more switching devices such as a MOSFET or an insulated gate bipolar transistor (IGBT), and one or more diode devices such as an SBD or a fast recovery diode (FRD) are used, as shown in FIG. 1, a number of semiconductor devices (e.g., switching device, diode device, or the like) are mounted on an insulating substrate (or a metal frame) on which a metal pattern such as direct bonded copper (DBC), direct plated copper (DPC), thick print copper (TPC), or active metal brazing (AMB) is formed, and the switching device and the diode device, and the device and the insulating substrate are connected via a bonding wire. Hereinafter, the insulating substrate or metal frame is collectively referred to as “insulating substrate”.

This embodiment provides a structure for reducing parasitic inductance due to bonding wires when packaging a semiconductor package in which one switching device and one diode device are integrated or a power module in which a plurality of switching devices and a plurality of diode devices are integrated as shown in FIG. 1. To this end, a flat metal 40 is stacked on a switching device 20 such as a MOSFET mounted on an insulating substrate 10 as shown in FIGS. 4A to 4C, and a diode device 30 such as an SBD is flipped and stacked on the flat metal 40 to implement a flip-stack type semiconductor package structure.

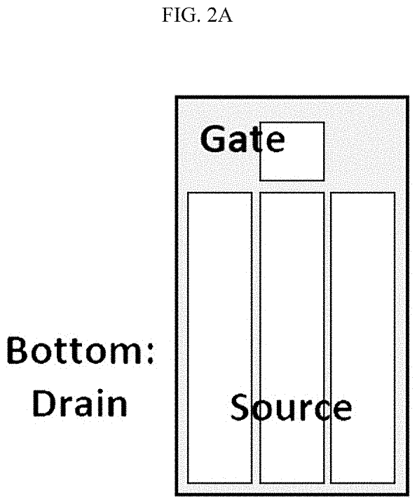

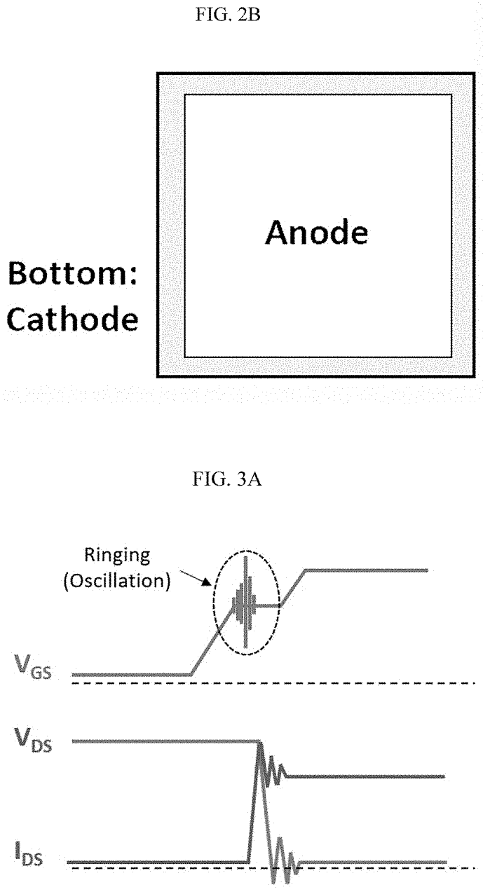

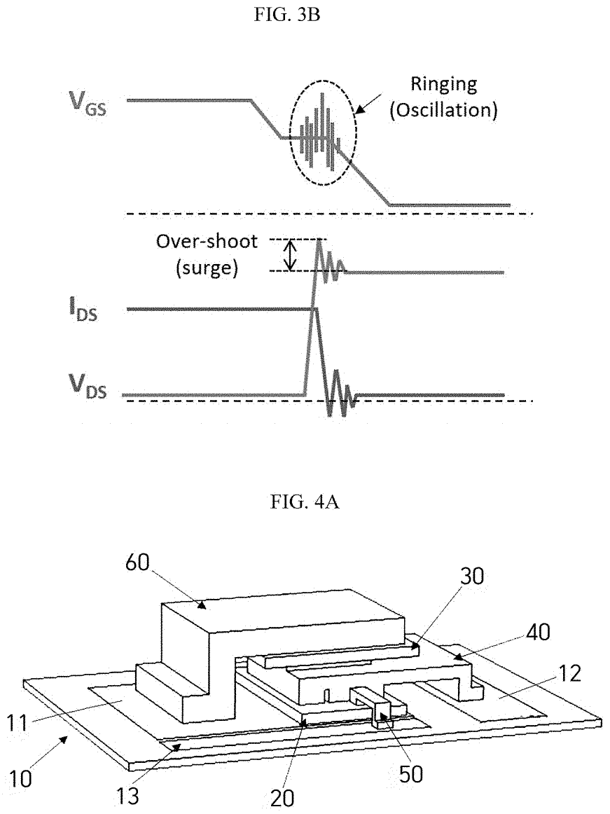

For example, when the power module of the circuit shown in FIG. 1 is configured using the switching device in which the bottom surface is the drain electrode and on the top surface the source electrode and the gate electrode are formed as shown in FIG. 2A, and the diode device in which the bottom surface is the cathode and the top surface is the anode as shown in FIG. 2B, the switching device 20 is mounted so that the drain of the bottom surface of the switching device 20 is in contact with a drain region 11 formed on the insulating substrate 10 as shown in FIGS. 4A to 4C.

The diode device 30 is flipped and stacked on the switching device 20 so that the source electrode on the top surface of the switching device 20 and the anode electrode on the top surface of the diode device 30 are electrically connected via a first flat metal 40. The other side of the first flat metal 40 is connected to a source region 12 formed on the insulating substrate 10.

Meanwhile, the gate electrode on the top surface of the switching device 20 is connected to a gate region 13 formed on the substrate 10 via a second flat metal 50 or a wire.

In addition, a cathode region of the flipped (i.e., flipped and mounted) diode device 30 is connected to a drain region 11 formed on the insulating substrate 10 via a third flat metal 60.

As described above, in order to flip and stack the diode device 30 on the switching device 20, the flat metals 40, 50, and 60 are required. Among them, for the gate of the switching device 20 or the cathode of the diode device 30, a bonding wire instead of the flat metals 50 and 60 may be used.

Although, in this embodiment, examples of MOSFET and SBD are described as the switching device 20 and the diode device 30, it is not limited to the MOSFET and the SBD because the present invention relates to a semiconductor package structure capable of reducing parasitic inductance of a semiconductor package.

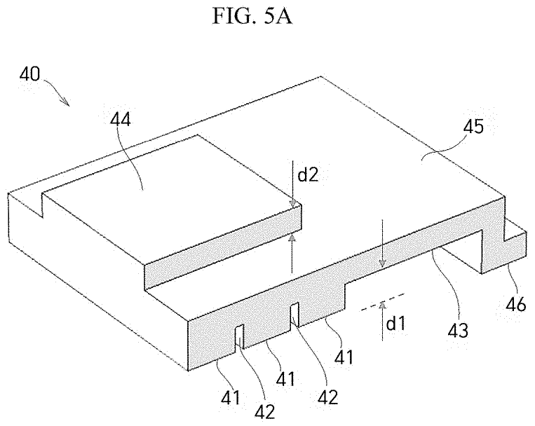

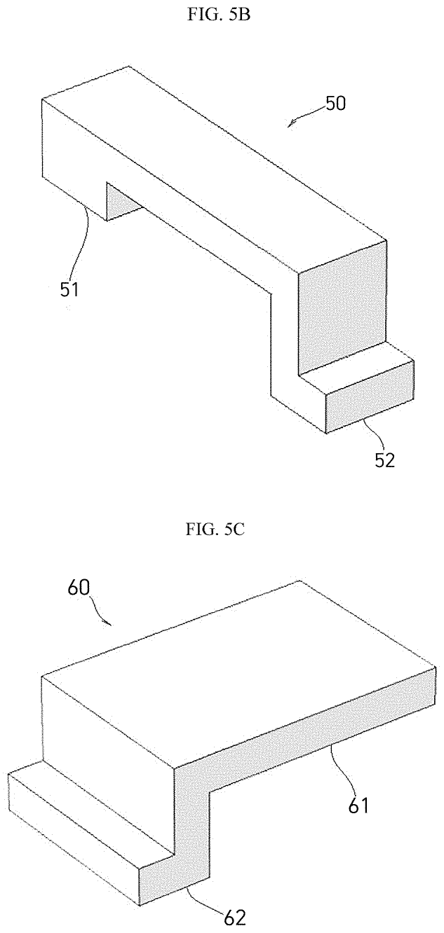

The flat metals 40, 50, and 60 will be exemplarily described with reference to FIGS. 5A to 5C. FIG. 5A is a three-dimensional structural diagram of the first flat metal 40, FIG. 5B is a three-dimensional structural diagram of the second flat metal 50, and FIG. 5C is a three-dimensional structural diagram of the third flat metal 60.

The first flat metal 40 shown in FIG. 5A has a switching device source junction 41 which is bonded to the source electrode on the top surface of the switching device 20. The switching device source junction 41 is also separated into three surfaces with gaps 42 interposed therebetween so as to be in contact with the source electrode formed separately in three on the top surface of the MOSFET exemplified in FIG. 2A. However, this is just an example, and it may be modified according to a shape of the source electrode positioned on the top surface of the MOSFET, and it is also possible to form the switching device source junction 41 with a single surface without the gaps.

The switching device source junction 41 is formed to descend by a step d1 from a bottom surface 44 of the first flat metal 40 to secure a gap between the flat metal 40 and the switching device 20. In a case of a high-voltage device, if the gap between the flat metal and the device is narrow, the reverse breakdown voltage characteristic of the device may degrade due to arc discharge. Therefore, the step d1 is provided to secure the gap between the flat metal and the device. In a case of an device of 1200V or more, the step d1 for the separation between the flat metal 40 and the switching device 20 may preferably be about 100 μm or more.

In addition, the first flat metal 40 has a diode device anode junction 44 in which the anode on the top surface of the diode device 30 is flipped and bonded downward at the upper portion thereof. The diode device anode junction 44 is also formed in a protruding part protruding by a step d2 from a main surface 45 in order to secure a gap between the upper main surface 45 of the flat metal 40 and the diode device 30. The step d2 is also for the same purpose as the step d1, and in the case of the device of 1200 V or more, the step d2 may be about 100 μm or more similar to the step d1.

In addition, the first flat metal 40 has a substrate source junction 46 bonded to the source region 12 on the insulating substrate 10. The first flat metal 40 and the insulating substrate 10 may be bonded by soldering.

Next, the second flat metal 50 shown in FIG. 5B is a flat metal that serves to connect the gate electrode on the top surface of the switching device 20 and the gate region 13 on the insulating substrate 10. The second flat metal 50 has a switching device gate junction 51 bonded to the gate electrode on the top surface of the MOSFET exemplified in FIG. 2A, and a substrate gate junction 52 bonded to the gate region 13 on the insulating substrate 10.

The second flat metal 50 may also include a step similar to the steps d1 and d2 of the first flat metal 40 in order to secure the gap between the switching device 20 and the diode device 30.

Lastly, the third flat metal 60 shown in FIG. 5C has a diode device cathode junction 61 bonded to the cathode positioned on the flipped diode device 30, and a substrate drain junction 62 bonded to the drain region 11 of the insulating substrate 10.

An overall shape of each flat metal described above and a shape of a portion in which each device and the substrate are bonded may be modified according to a shape of the corresponding device and a shape of a pad or region to be bonded. And, the thickness of each flat metal is determined according to the current capacity of the power module.

As described above, since the flat metals 40, 50, and 60 according to the present invention have a relatively large area compared to a conventional bonding wire, the problem of ringing or over-shooting due to parasitic inductance generated in using the bonding wire is solved.

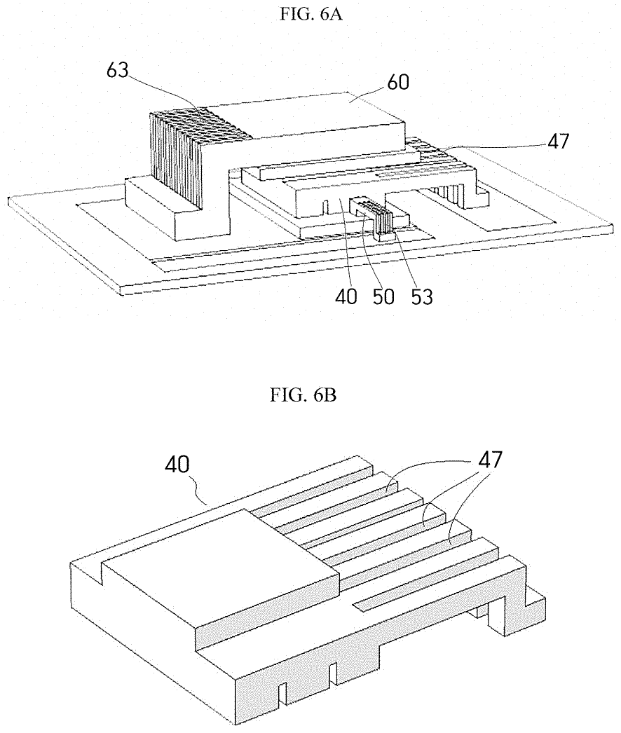

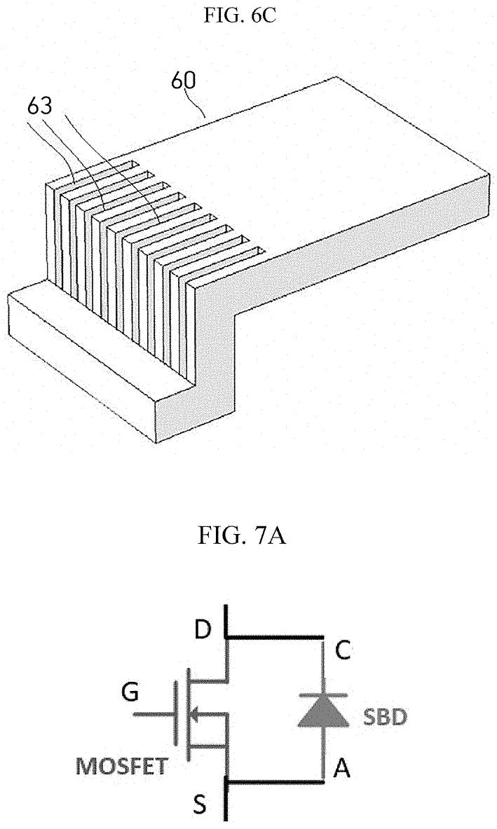

FIGS. 6A to 6C show modified examples of each flat metal and show the flat metals implemented in a comb shape including one or more slots to reduce inductance and easily remove voids occurring under the flat metal. FIG. 6A is a three-dimensional schematic diagram of a flip-stack type semiconductor package structure according to this embodiment, FIG. 6B shows the first flat metal 40, and FIG. 6C shows the third flat metal 60. Here, the slot may be included in at least one of the first flat metal 40, the second flat metal 50, and the third flat metal 60, if necessary.

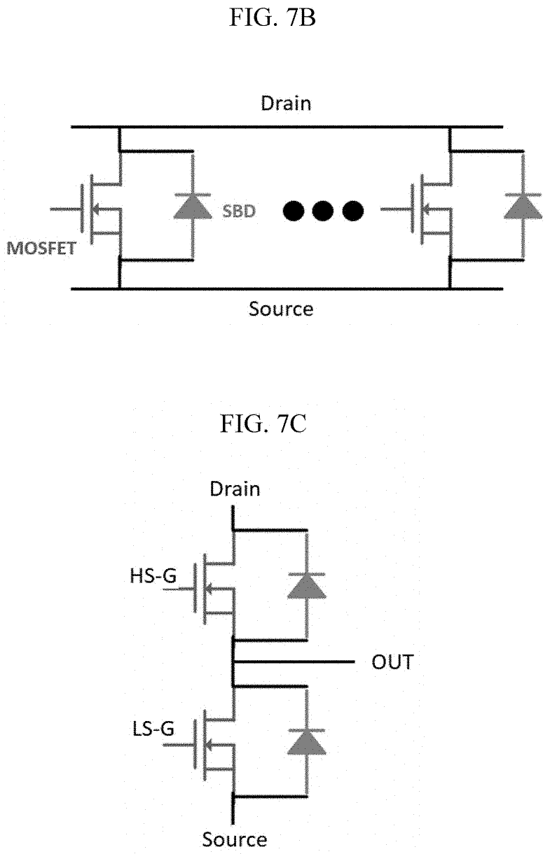

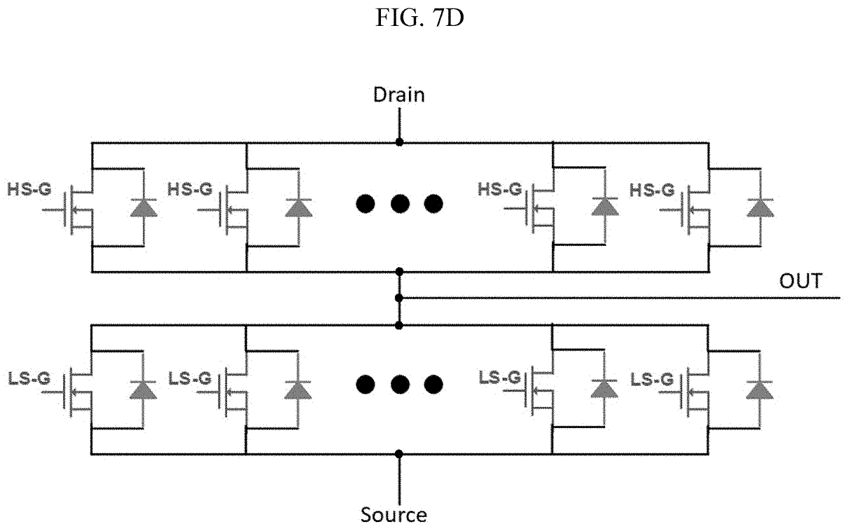

FIGS. 7A to 7D show various circuits applicable to the flip-stack type semiconductor package of the present invention and show examples of circuits using a MOSFET as the switching device and an SBD as the diode device. FIG. 7A is a circuit in which the MOSFET and the SBD are connected in parallel and shows a unit circuit used in the power module circuit shown in FIG. 1. FIG. 7B is a circuit in which a plurality of MOSFETs and a plurality of SBDs are connected in parallel and shows one of an upper circuit and a lower circuit of the power module circuit diagram shown in FIG. 1. FIG. 7C shows a half-bridge circuit in which two MOSFETs are connected in series and SBDs are connected in parallel to each of the MOSFETs. FIG. 7D shows a half-bridge circuit in which a first group in which a plurality of MOSFETs are connected in parallel and a second group in which a plurality of SBDs are connected in parallel are connected up and down, and shows the same circuit as the power module circuit shown in FIG. 1.

Devices and circuits applicable to the flip-stack type semiconductor package according to the present invention are not limited by these examples.

Now, a process of a manufacturing method of the flip-stack type semiconductor package according to the present invention will be described. In the following description, a method of manufacturing the power module in which the MOSFET is used as the switching device and the SBD is used as the diode device is described as an example (see FIGS. 4A and 6A).

First, solder is applied to a MOSFET soldering region and each flat metal soldering region formed on the insulating substrate 10. A MOSFET is mounted on the insulating substrate 10 in a region in which solder is applied. Solder is applied to a source and a gate at the top of the mounted MOSFET, and solder is applied to a position of the insulating substrate 10 to which the first flat metal 40 and the second flat metal 50 are to be bonded. The first flat metal 40 and the second flat metal 50 are mounted on the source and gate of the MOSFET and the insulating substrate 10. Solder is applied to a region of the first flat metal 40 to which an SBD is to be bonded, and the SBD is flipped and mounted so that an anode of the SBD is in contact with the region of the first flat metal 40 on which the solder is applied. Solder is applied to a cathode of the SBD that is flipped and mounted, and the third flat metal 60 is mounted on the solder. The MOSFET, the SBD, the flat metals 40, 50, and 60, and the insulating substrate 10 are soldered and bonded at the same time.

Accordingly, the flip-stack type power module package as shown in FIG. 4A or 6A may be manufactured. The present invention enables complete automization of power module manufacturing, which was not possible with the conventional technology, thereby reducing manufacturing time and reducing cost.

According to the present invention, in packaging a power module composed of one or more switching devices and one or more diode devices, the diode device is flip-stacked and connected to the switching device, and each device and the insulating substrate are connected using a flat metal, and thus it is possible to obtain an effect that parasitic inductance of the power module can be minimized and the manufacturing cost can be reduced through automization of manufacturing.

Although the present invention has been described in detail above with reference to the exemplary embodiments, those of ordinary skill in the technical field to which the present invention pertains should be able to understand that various modifications and alterations can be made without departing from the technical spirit or essential features of the present invention. Therefore, it should be understood that the disclosed embodiments are not limiting but illustrative in all aspects. The scope of the present invention is defined not by the above description but by the following claims, and it should be understood that all changes or modifications derived from the scope and equivalents of the claims fall within the scope of the present invention.

What is claimed is:

1. A flip-stack type semiconductor package, comprising:
an insulating substrate;
one or more switching devices mounted on the insulating substrate;
a first flat metal positioned on a top surface of the switching device; and
one or more diode devices flip-stacked on the first flat metal.

2. The semiconductor package of claim 1, wherein the switching device is a metal-oxide-semiconductor field-effect transistor (MOSFET) in which a bottom surface is a drain electrode and, on a top surface thereof, source and gate electrodes are formed, and
the diode device is a Schottky barrier diode (SBD) of which a bottom surface is a cathode and a top surface is an anode.

3. The semiconductor package of claim 1, wherein the first flat metal is connected to the insulating substrate.

4. The semiconductor package of claim 1, further comprising a second flat metal connecting the top surface of the switching device and the insulating substrate.

5. The semiconductor package of claim 1, further comprising a third flat metal connecting a flipped bottom surface of the flip-stacked diode device and the insulating substrate.

6. The semiconductor package of claim 1, wherein the first flat metal includes a step for securing a distance from at least one of the switching device and the diode device.

7. The semiconductor package of claim 1, wherein the first flat metal includes one or more slots.

8. The semiconductor package of claim 4, wherein the second flat metal includes one or more slots.

9. The semiconductor package of claim 5, wherein the third flat metal includes one or more slots.

10. A method of manufacturing a flip-stack type semiconductor package, the method comprising:
forming a switching device soldering region and a first flat metal soldering region on an insulating substrate;
applying solder to the switching device soldering region and the first flat metal soldering region, and mounting one or more switching devices in the switching device soldering region;
applying solder to a first electrode on a top surface of the switching device and mounting a first flat metal in the first flat metal soldering region on which the solder is applied and which is formed on the insulating substrate;
applying solder to a first flat metal region to which a diode device is bonded, and flipping and mounting the diode device so that the diode device is in contact with the first flat metal region on which the solder is applied; and
soldering and bonding the switching device, the diode device, the first flat metal, and the insulating substrate at the same time.

11. The method of claim 10, wherein the switching device is a metal-oxide-semiconductor field-effect transistor (MOSFET) in which a bottom surface is a drain electrode and, on a top surface thereof, source and gate electrodes are formed, and the diode device is a Schottky barrier diode (SBD) of which a bottom surface is a cathode and a top surface is an anode.

12. The method of claim 10, further comprising:
forming a second flat metal soldering region on the insulating substrate;
applying solder to a second electrode on the top surface of the switching device, and mounting a second flat metal in the second flat metal soldering region on which the solder is applied and which is formed on the insulating substrate; and
soldering and bonding the switching device, the diode device, the first flat metal, the second flat metal, and the insulating substrate at the same time.

13. The method of claim 10, further comprising:
forming a third flat metal soldering region on the insulating substrate;
applying solder to the flipped bottom surface of the diode device flipped and mounted on the first flat metal, and mounting a third flat metal in the third flat metal soldering region on which the solder is applied and which is formed on the insulating substrate; and
soldering and bonding the switching device, the diode device, the first flat metal, a second flat metal, the third flat metal, and the insulating substrate at the same time.
